(19) United States
(12) Patent Application Publication
(10) Pub. No.: US 2016/0211334 A1
(43) Pub. Date: Jul. 21, 2016

(54) SILICON CARBIDE SEMICONDUCTOR DEVICE AND METHOD FOR MANUFACTURING SAME

(71) Applicant: MITSUBISHI ELECTRIC CORPORATION, Tokyo (JP)

(72) Inventors: Rina TANAKA, Tokyo (JP); Yasuhiro KAGAWA, Tokyo (JP); Naruhisa MIURA, Tokyo (JP); Yuji ABE, Tokyo (JP); Yutaka FUKUI, Tokyo (JP); Takaaki TOMINAGA, Tokyo (JP)

(73) Assignee: MITSUBISHI ELECTRIC CORPORATION, Chiyoda-ku, Tokyo (JP)

(21) Appl. No.: 15/023,561

(22) PCT Filed: Jun. 13, 2014
(86) PCT No.: PCT/JP2014/003168

§ 371 Date: Mar. 21, 2016

(30) Foreign Application Priority Data
Oct. 4, 2013 (JP) 2013-208763

(51) Int. Cl. H01L 29/16; H01L 29/06; H01L 29/78; H01L 29/739; H01L 29/10; H01L 29/423

(52) U.S. Cl. CPC H01L 29/1608; H01L 29/1095; H01L 29/4236; H01L 29/7813; H01L 29/7397; H01L 29/0623

(57) ABSTRACT

A silicon carbide semiconductor device capable of decreasing an ON-state resistance and improving a breakdown voltage. The silicon carbide semiconductor device includes: a drift layer of a first conductivity type made of a silicon carbide semiconductor; a depletion suppression layer of the first conductivity type formed on the drift layer and having a first conductivity type impurity concentration higher than that of the drift layer; a body region of a second conductivity type formed on the depletion suppression layer; a trench extending through the body region and the depletion suppression layer to reach the drift layer; and a gate insulation film formed along bottom and side surfaces of the trench. The depletion suppression layer has a thickness equal to or greater than 0.06 μm and equal to or less than 0.31 μm.

### TECHNICAL FIELD

The present invention relates to a silicon carbide semiconductor device and a method for manufacturing the same and, more particularly, to a trench gate type silicon carbide semiconductor device and a device thereof.

### BACKGROUND ART

Insulated gate type semiconductor devices such as a MOSFET (Metal Oxide Semiconductor Field Effect Transistor) and an IGBT (Insulated Gate Bipolar Transistor) have been widely used as power switching elements. In an insulated gate type semiconductor device, the application of voltage equal to or greater than a threshold voltage to a gate electrode forms a channel to turn on the insulated gate type semiconductor device. To improve a channel width density in such an insulated gate type semiconductor device, a trench gate type semiconductor device in which a trench is formed in a semiconductor layer and a well region on a side surface of the trench is used as a channel has been brought into practical use. This achieves the reduction in cell pitch to improve device performance.

Attention has been given to semiconductor devices employing silicon carbide (SiC) (referred to hereinafter as “silicon carbide semiconductor devices”) as next-generation semiconductor devices which achieve high breakdown voltage and low losses, and the development of trench gate type silicon carbide semiconductor devices has been advanced. It has been proposed to provide an n-type current diffusion layer lying between a p-type well region and an n-type drift layer and having an impurity concentration higher than that of the drift layer in a conventional trench gate type silicon carbide semiconductor device for the purpose of decreasing an ON-state resistance (with reference to Patent Documents 1 and 2). The provision of the current diffusion layer in this manner causes current to diffuse laterally widely and flow through the current diffusion layer after electrons pass through a channel formed in the well region on the side surface of the trench, so that the ON-state resistance is decreased.

### PRIOR ART DOCUMENTS

### Patent Documents

Patent Document 1: Japanese Unexamined Patent Application Publication (Translation of PCT Application) No. 2001-511315
Patent Document 2: Japanese Patent Application Laid-Open No. 2012-238887

### SUMMARY OF INVENTION

### Problems to be Solved by the Invention

In a silicon carbide semiconductor device, the dielectric breakdown in the drift layer is suppressed by the high dielectric breakdown strength of silicon carbide, so that a breakdown voltage is improved. In a trench gate type semiconductor device, electric field concentration occurs in a trench bottom portion and, in particular, in a gate insulation film at a corner of the trench bottom portion when the semiconductor device is in an OFF state in which a high voltage is applied between a drain electrode and a source electrode. In a trench gate type silicon carbide semiconductor device, there has been a danger that the suppression of the dielectric breakdown in the drift layer causes an insulation film breakdown to initiate at the gate insulation film in the trench bottom portion, so that the breakdown voltage is limited.

To solve such a problem, it can be contemplated for the trench gate type silicon carbide semiconductor device to ensure a distance from the drain electrode by forming a shallow trench, thereby relieving the electric field applied to the gate insulation film in the trench bottom portion. However, when the current diffusion layer is provided for the purpose of decreasing the ON-state resistance, the formation of the trench bottom portion inside the current diffusion layer increases the electric field in the trench bottom portion. It is hence necessary that the trench extends through the current diffusion layer to reach the drift layer. For this reason, the provision of the current diffusion layer makes the trench deeper by the amount of the thickness of the current diffusion layer to give rise to a problem such that the electric field in the trench bottom portion is increased to decrease the breakdown voltage.

The present invention has been made to solve the aforementioned problem. It is therefore an object of the present invention to provide a silicon carbide semiconductor device capable of decreasing an ON-state resistance and improving a breakdown voltage.

### Means to Solve the Problem

A silicon carbide semiconductor device according to the present invention includes: a drift layer of a first conductivity type made of a silicon carbide semiconductor; a depletion suppression layer of the first conductivity type formed on the drift layer and having a first conductivity type impurity concentration higher than that of the drift layer; a well region of a second conductivity type formed on the depletion suppression layer; a trench extending through the well region and the depletion suppression layer to reach the drift layer; and a gate insulation film formed along bottom and side surfaces of the trench, wherein the depletion suppression layer has a thickness equal to or greater than 0.06 and equal to or less than 0.31 μm.

### Effects of the Invention

In the silicon carbide semiconductor device according to the present invention, the depletion suppression layer having an impurity concentration higher than that of the drift layer is formed on the drift layer. The thickness of the depletion suppression layer is not less than 0.06 μm. This suppresses a depletion layer extending from the well region to decrease an ON-state resistance. Also, the thickness of the depletion suppression layer is not greater than 0.31 μm. This makes the trench shallower to relieve an electric field in a bottom portion of the trench, thereby improving a breakdown voltage.

### BRIEF DESCRIPTION OF DRAWINGS

FIG. 1 is a sectional view showing a cell of a silicon carbide semiconductor device according to a first embodiment.

FIG. 2 is a sectional view showing a method for manufacturing the silicon carbide semiconductor device according to the first embodiment.

FIG. 3 is a sectional view showing the method for manufacturing the silicon carbide semiconductor device according to the first embodiment.

FIG. 4 is a sectional view showing the method for manufacturing the silicon carbide semiconductor device according to the first embodiment.

FIG. 5 is a sectional view showing the method for manufacturing the silicon carbide semiconductor device according to the first embodiment.

FIG. 6 is a graph showing a relationship between a depletion layer width in an n-type region at a pn junction and an n-type impurity concentration.

FIG. 7 is a graph showing a relationship between the depletion layer width in the n-type region at the pn junction and temperature.

FIG. 8 is a sectional view showing a trench of the silicon carbide semiconductor device according to the first embodiment.

FIG. 9 is a sectional view showing a cell of the silicon carbide semiconductor device according to a modification of the present invention.

FIG. 10 is a sectional view showing a method for manufacturing the silicon carbide semiconductor device according to the modification of the present invention.

FIG. 11 is a plan view relating to a cell pattern of the semiconductor device according to the first embodiment.

FIG. 12 is a plan view relating to a cell pattern of the semiconductor device according to the first embodiment.

FIG. 13 is a sectional view showing a cell of the silicon carbide semiconductor device according to a comparative example of the present invention.

FIG. 14 is a view showing a distribution of an ON-state current density of the silicon carbide semiconductor device according to the comparative example of the present invention.

FIG. 15 is a view showing a distribution of an ON-state current density of the silicon carbide semiconductor device according to the first embodiment.

FIG. 16 is a graph showing an electric field strength in the first embodiment and in the comparative example.

FIG. 17 is a sectional view showing a cell of the silicon carbide semiconductor device according to a second embodiment.

FIG. 18 is a sectional view showing a cell of the silicon carbide semiconductor device according to a third embodiment.

FIG. 19 is a sectional view showing a cell of the silicon carbide semiconductor device according to a fourth embodiment.

### DESCRIPTION OF EMBODIMENTS

### First Embodiment

The configuration of a silicon carbide semiconductor device according to a first embodiment will be described. FIG. 1 is a sectional view showing a cell of a silicon carbide semiconductor device 100 according to the first embodiment. In the following paragraphs, an “impurity concentration” shall refer to a peak value of impurities in each region, and the “width” and “thickness” of each region in a case where the impurity concentration of each region has a concentration distribution shall refer to the width and thickness of a region in which the impurity concentration is equal to or greater than one-half of the peak value of the impurity concentration in the region.

In FIG. 1, the silicon carbide semiconductor device 100 includes a substrate 1, a semiconductor layer 20, a source electrode 11 and a drain electrode 12. The semiconductor layer 20 is formed on the front surface of the substrate 1. The source electrode 11 is formed on the semiconductor layer 20. The drain electrode 12 is formed on the back surface of the substrate 1. A trench 7 is formed in a surface of the semiconductor layer 20. A gate insulation film 9 and a gate electrode 10 are formed in the trench 7. Although the source electrode 11 is formed on the surface of the semiconductor layer 20, an interlayer dielectric film 8 is formed on a region of the surface of the semiconductor layer 20 which lies over the trench 7 so as to cover the gate electrode 10.

The substrate 1 is an n-type silicon carbide semiconductor substrate. The semiconductor layer 20 is formed on the front surface of the substrate 1, and the drain electrode 12 is formed on the back surface thereof. The semiconductor layer 20 is a semiconductor layer formed by the epitaxial growth of a silicon carbide semiconductor. The semiconductor layer 20 has a source region 3, a well contact region 4, a well region 5 and a depletion suppression layer 6. The remaining region of the semiconductor layer 20 serves as a drift layer 2.

The drift layer 2 is an n-type semiconductor layer positioned on the substrate 1, and is a semiconductor layer having an n-type impurity concentration lower than that of the substrate 1. The depletion suppression layer 6 is formed on the drift layer 2. The depletion suppression layer 6 is an n-type semiconductor layer, and is a semiconductor layer having an n-type impurity concentration higher than that of the drift layer 2. The body region 5 is formed on the depletion suppression layer 6. The body region 5 is a p-type semiconductor region. The body contact region 4 and the source region 3 are formed on the body region 5. The body contact region 4 is a p-type semiconductor region, and is a region having a p-type impurity concentration higher than that of the body region 5. The source region 3 is a n-type semiconductor region.

The trench 7 is formed so as to extend from the surface of the semiconductor layer 20, more specifically from the surface of the source region 3, through the body region 5 and the depletion suppression layer 6 to reach the drift layer 2. The gate insulation film 9 is formed on the bottom and side surfaces in the trench 7. The gate electrode 10 is formed on the gate insulation film 9 and embedded in the trench 7.

The source electrode 11 is formed in contact with the source region 3 and the body contact region 4 on the surface of the semiconductor layer 20. The source electrode 11 is made of a silicide of metal such as Ni and Ti and the semiconductor layer 20, and makes an ohmic contact with the source region 3 and the body contact region 4. The drain electrode 12 is formed on the back surface of the substrate 1, and is a metal electrode such as Ni.

Next, the impurity concentration of each of the semiconductor layers and regions will be described. The drift layer 2 has an n-type impurity concentration of 1.0×10¹⁴ to 1.0×10¹⁷ cm⁻³, which is set based on the breakdown voltage and the like of the silicon carbide semiconductor device 100. The body region 5 has a p-type impurity concentration of 1.0×10¹⁴ to 1.0×10¹⁸ cm⁻³. The source region 3 has an n-type impurity concentration of 1.0×10¹⁸ to 1.0×10²¹ cm⁻³. The body contact region 4 has a p-type purity concentration of 1.0×10¹⁸ to 1.0×10²¹ cm⁻³, which is higher than that of the body region 5 for the purpose of decreasing a contact resistance with the source electrode 11.

The depletion suppression layer 6 has an n-type impurity concentration of not less than 1.0×10¹⁷, more preferably in the range of 2.0×10¹⁷ to 5.0×10¹⁷ cm⁻³, which is higher than that of the drift layer 2, and suppresses a depletion layer extending from the body region 5. The thickness of the depletion suppression layer 6 and the depth of the trench 7 will be described in the description of a method for manufacturing the silicon carbide semiconductor device 100 which will be described later.

Next, the operation of the silicon carbide semiconductor device 100 will be described briefly. When voltage equal to or greater than a threshold voltage is applied to the gate electrode 10 with reference to FIG. 1, a channel of opposite conductivity type to the body region 5, i.e. of an n-type, is formed in the body region 5 along the side surfaces of the trench 7. Then, a current path of the same conductivity type extends from the source electrode 11 to the drain electrode 12, so that current is caused to flow by applying voltage between the drain electrode 12 and the source electrode 11. A state in which voltage equal to or greater than the threshold voltage is applied to the gate electrode 10 in this manner is the ON state of the silicon carbide semiconductor device 100.

On the other hand, when voltage equal to or less than the threshold voltage is applied to the gate electrode 10, no channel is formed in the body region 5, so that the current path as in the ON state is not formed. Thus, no current flows from the drain electrode 12 to the source electrode 11 even when voltage is applied between the drain electrode 12 and the source electrode 11. A state in which voltage equal to or less than the threshold voltage is applied to the gate electrode 10 in this manner is the OFF state of the silicon carbide semiconductor device 100. By controlling the voltage applied to the gate electrode 10, the silicon carbide semiconductor device 100 is switched between the ON state and the OFF state to operate.

Next, a method for manufacturing the silicon carbide semiconductor device 100 will be described. FIGS. 2 to 4 are sectional views showing steps of the method for manufacturing the silicon carbide semiconductor device according to the first embodiment.

With reference to FIG. 2, the substrate 1 on which the n-type semiconductor layer 20 made of silicon carbide is formed is prepared. More specifically, the n-type semiconductor layer 20 may be formed by an epitaxial growth technique on the substrate 1 that is an n-type silicon carbide substrate. The n-type impurity concentration of the semiconductor layer 20 is formed to correspond to the n-type impurity concentration of the drift layer 2 described above.

With reference to FIG. 3, the source region 3, the body contact region 4, the body region 5 and the depletion suppression layer 6 are formed by ion implantation in an upper part of the semiconductor layer 20. The ion implantation is performed in such a manner that N ions, for example, are implanted as a donor for the formation of an n-type region, and Al ions, for example, are implanted as an acceptor for the formation of a p-type region. The impurity concentrations of the respective regions are formed so as to have the aforementioned values. The order in which the regions are formed may be different from the order named. All or part of the regions may be formed by epitaxial growth instead of the ion implantation. Although details about the thickness of the depletion suppression layer 6 and the like will be described later, it is desirable in the first embodiment that the ion implantation which causes smaller in-plane variations is used to form the depletion suppression layer 6 for the purpose of making the depletion suppression layer 6 thinner than the conventional current diffusion layer.

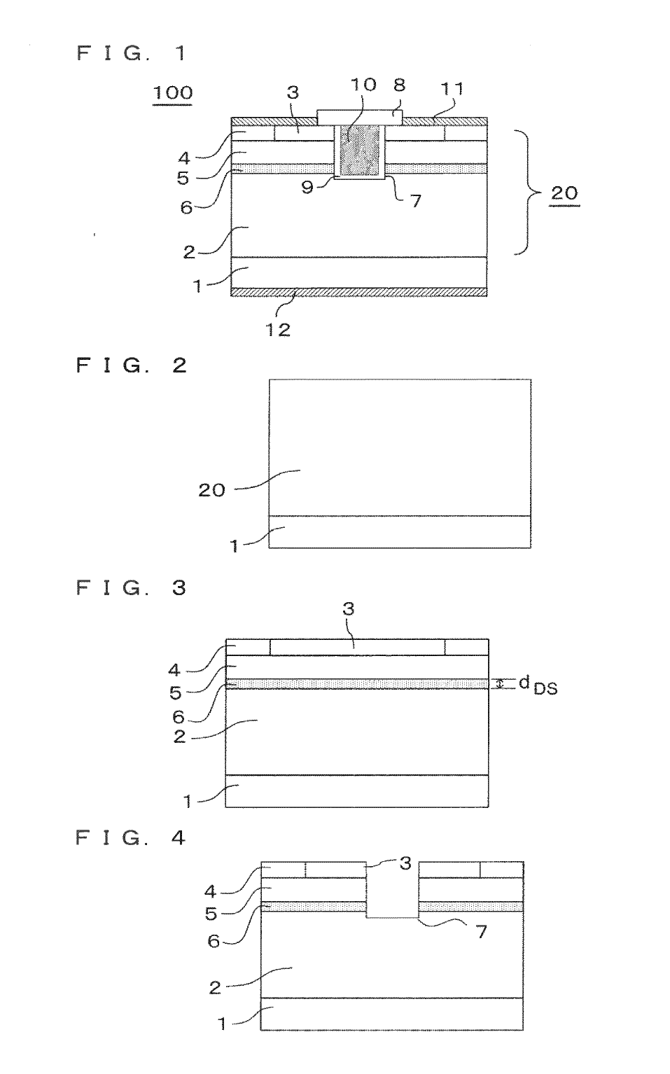

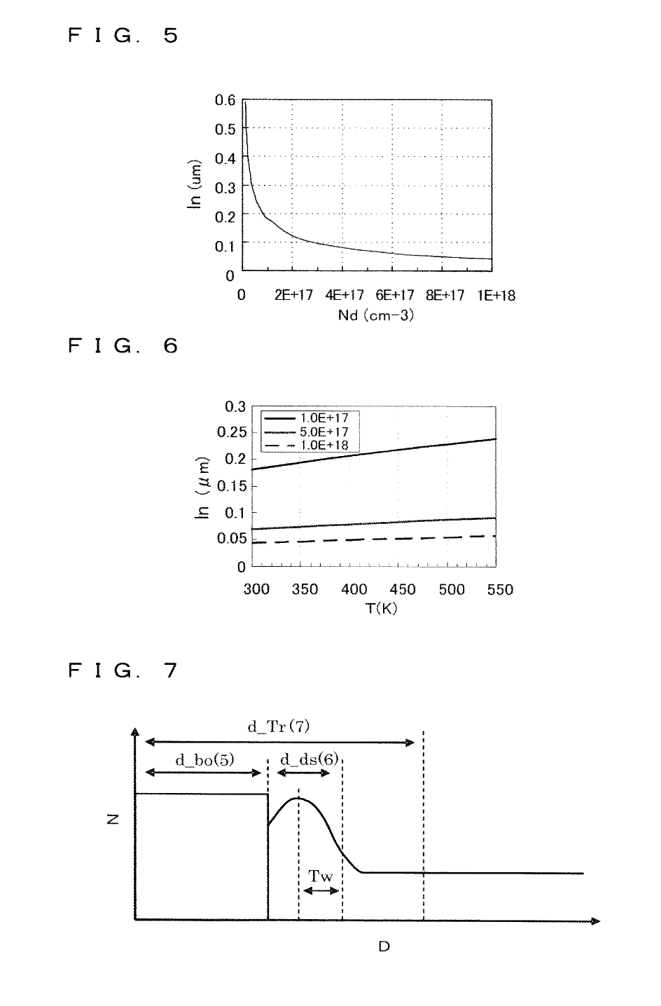

With reference to FIG. 4, the trench 7 extending from the surface of the source region 3 through the body region 5 and the depletion suppression layer 6 to reach the drift layer 2 is formed by reactive ion etching (RIE). The depth of the trench 7 will be described later.

Thereafter, the gate insulation film 9 is formed on the bottom and side surfaces in the trench 7. The gate electrode 10 is formed on the gate insulation film 9 so as to be embedded in the trench 7. After the interlayer dielectric film 8 is formed so as to cover the gate electrode 10, the source electrode 11 is formed in contact with the surface of the source region 3 and the surface of the body contact region 4, and the drain electrode 12 is formed on the back surface of the substrate 1. The silicon carbide semiconductor device 100 shown in FIG. 1 is produced by the aforementioned steps.

Next, the thickness of the depletion suppression layer 6 will be described. The thickness of the depletion suppression layer 6 is set so as to suppress the depletion layer extending from the body region 5 at the pn junction between the body region 5 and the depletion suppression layer 6 toward the drift layer 2 with reliability. Specifically, the thickness of the depletion suppression layer 6 is set, based on the depletion layer width ln of an n-type region calculated using Equation (1) from the p-type impurity concentration of the body region 5, the n-type impurity concentration of the depletion suppression layer 6 and a voltage (ON-state voltage) applied between the drain electrode 12 and the source electrode 11 in the ON state. The depletion layer width ln of the n-type region shall be the width of the depletion layer extending from a boundary between the body region 5 and the depletion suppression layer 6 toward the depletion suppression layer 6.

$$\begin{matrix}[ Math . 1 ] & \\ {l}_{n} = \frac{{N}_{a}}{{N}_{a} + {N}_{d}} \sqrt{\frac{2 {ɛ}_{s}}{q} ( \frac{1}{{N}_{a}} + \frac{1}{{N}_{d}} ) ( {Φ}_{bi} - {V}_{a} )} & ( 1 )\end{matrix}$$

In Equation (1), Na is an acceptor concentration (the p-type impurity concentration of the body region 5), Nd is a donor concentration (the n-type impurity concentration of the depletion suppression layer 6), ∈ₛ is a vacuum permittivity, q is an elementary charge, Φ_{bi} is a diffusion potential and Va is an applied bias (ON-state voltage). The diffusion potential φ_{bi} is determined using Equation (2).

$$\begin{matrix}[ Math . 2 ] & \\ {Φ}_{bi} = \frac{kT}{q} ln \frac{{N}_{a} {N}_{d}}{{n}_{i}^{2}} & ( 2 )\end{matrix}$$

In Equation (2), k is the Boltzmann constant, T is temperature and ni is an intrinsic carrier density.

FIG. 5 shows a relationship between the depletion layer width ln calculated by Equation (1) and the donor concentration Nd. In FIG. 5, the ordinate represents the depletion layer width ln of the n-type region, and the abscissa represents the donor concentration Nd. The depletion layer width ln calculated by Equation (1) shall be the width of the depletion layer at room temperature (25° C.). In the specific calculation of the depletion layer width ln to be described below, the acceptor concentration Na shall be the highest one (1.0×10¹⁸ cm⁻³) of the impurity concentrations of the body region 5 that are conceivable in the first embodiment. For the calculation of the depletion layer width In, it is assumed that the acceptor concentration Na=1.0×10¹⁸ cm⁻³ unless otherwise specified.

In FIG. 5, the depletion layer width ln has a tendency to increase as the donor concentration Nd decreases. In particular, it is found that the depletion layer width In abruptly starts increasing when the donor concentration Nd falls below 1.0×10¹⁷ cm⁻³. That is, the impurity concentration in the range of not less than 1.0×10¹⁷ cm⁻³ is an effective impurity concentration for suppressing the depletion layer width ln. It is also found that the amount of suppression of the depletion layer width ln remains practically unchanged even when the impurity concentration is not less than 2.0×10¹⁷ cm⁻³, and particularly not less than 5.0×10¹⁷ cm⁻³. The rate of decrease in the depletion layer width ln (the absolute value of the slope of the curve in the graph of FIG. 5) with respect to the donor concentration in the range of not greater than 1.0×10¹⁷ cm⁻³ is approximately not less than 20 times that in the range of not less than 1.0×10¹⁷ cm⁻³. Thus, the impurity concentration in the range of not less than 1.0×10¹⁷ cm⁻³ is an effective impurity concentration for suppressing the depletion layer width In. Also, the rate of increase in the depletion layer width ln in the range of not less than 2.0×10¹⁷ cm⁻³ is reduced to not more than 10 times as compared with the depletion layer width around 1.0×10¹⁸ cm⁻³, which is more effective. Also, variations in depletion layer width ln are made smaller by making the donor concentration Nd much higher. In particular, when the impurity concentration is not less than 5.0×10¹⁷ cm⁻³, the depletion layer width In remains practically unchanged, and the rate of increase in depletion layer width ln is not greater than three times relative to the depletion layer around 1.0×10¹⁸ cm⁻³.

On the other hand, it is not desirable to unnecessarily increase the impurity concentration in consideration for the fact that the electric field in the semiconductor layer 20 increases with the increase in impurity concentration. For this reason, the n-type impurity concentration of the depletion suppression layer 6 in the first embodiment is no less than 1.0×10¹⁷ cm⁻³, and more preferably in the range of 2.0×10¹⁷ to 5.0×10¹⁷ cm⁻³. Then, the thickness of the depletion suppression layer 6 is set so as to be at least greater than the depletion layer width ln calculated using Equation (1) from the p-type impurity concentration of the body region 5 and the n-type impurity concentration of the depletion suppression layer 6.

The depletion layer width ln changes with a change in temperature. It is hence necessary to consider the change in temperature for the purpose of suppressing the depletion layer with reliability. FIG. 6 is a graph showing a relationship between the depletion layer width ln calculated by Equation (1) and temperature. In FIG. 6, the ordinate represents the depletion layer width ln [μm] of the n-type region, and the abscissa represents temperature T [K]. Curves plotted in FIG. 6 represent the depletion layer width ln for the n-type impurity concentrations of 1.0×10¹⁷ cm⁻³, 5.0×10¹⁷ cm⁻³ and 1.0×10¹⁸ cm⁻³.

It is found from FIG. 6 that the depletion layer width ln increases with the increase in temperature. In consideration for a temperature change from room temperature to the maximum operating temperature (200° C. to 300° C.) of approximately 500 [K] of the silicon carbide semiconductor device 100, it is found that the amount of increase in depletion layer width ln is within approximately 30% with respect to the depletion layer width ln at room temperature in any case of the n-type impurity concentration. Then, in consideration for a temperature change, it is desirable that the thickness of the depletion suppression layer 6 is within 100% to 130% of the depletion layer width ln at room temperature which is calculated using Equation (1) from the p-type impurity concentration of the body region 5 and the n-type impurity concentration of the depletion suppression layer 6. It is desirable that the thickness of the depletion suppression layer 6 is 60 to 240 nm under the conditions of the first embodiment. This achieves the suppression of the depletion layer while accommodating the increase in depletion layer width with a change in temperature, and also prevents the thickness of the depletion suppression layer 6 from unnecessarily increasing.

However, when the depletion suppression layer 6 is formed by ion implantation, it is necessary to further take the tail width of the impurity concentration resulting from the ion implantation into consideration. FIG. 7 shows a relationship between an impurity concentration and a depth in a three-layer structure comprised of the body region 5, the depletion suppression layer 6 and the drift layer 2 in the semiconductor layer 20. In FIG. 7, the ordinate represents the impurity concentration N, and the abscissa represents the depth D from the body region 5. In FIG. 7, d_Tr denotes the depth of the trench 7, d_bo denotes the thickness of the body region 5, d_ds denotes the thickness of the depletion suppression layer 6 and Tw denotes the tail width. The impurity concentration in the part d_bo is the p-type impurity concentration, and the impurity concentration in the remaining parts is the n-type impurity concentration.

When the depletion suppression layer 6 is formed by ion implantation, the impurity concentration of the depletion suppression layer 6 has a concentration distribution, as shown in FIG. 7. This produces a tail from a peak value to a value that is one-half the peak value in the impurity concentration of the depletion suppression layer 6. In a tail part, the impurity concentration is lower than the peak value. Thus, when the thickness of the depletion suppression layer 6 is set without consideration for the tail part, p-type impurities in the depletion suppression layer 6 are reduced by the amount of the decrease in the impurity concentration in the tail part. This results in a danger that the suppression of the depletion layer extending from the body region 5 is insufficient. It is hence necessary that the depletion suppression layer 6 is thicker by the amount of the tail width Tw. Although the depletion suppression layer 6 is formed by the single ion implantation process in FIG. 7, the present invention is not limited to this. The depletion suppression layer 6 may be formed by a plurality of ion implantation processes. In such a case, a tail corresponding to the single ion implantation process is produced in the deepest part of the depletion suppression layer 6.

The tail width Tw (on one side) is 60 to 70 nm when calculated by simulation in the range of the n-type impurity concentration of the depletion suppression layer 6 which is conceivable in the first embodiment. For the calculation of the tail width Tw, a simulation is performed on the assumption that an implantation energy is in the range of 700 to 1500 keV which are typical values. Thus, when the thickness of the depletion suppression layer 6 is set to 60 to 240 nm, the actual width of the depletion suppression layer 6 obtained by adding the tail width Tw to the set value is in the range of 120 to 310 nm in the first embodiment.

When the depletion suppression layer 6 is formed by epitaxial growth, rather than by ion implantation, the thickness of the depletion suppression layer 6 may be in the range of 60 to 240 nm as described above without the addition of the tail width Tw. The thickness of the depletion suppression layer 6 may be in the range of 60 to 310 nm in consideration for both of the cases in which the depletion suppression layer 6 is formed by ion implantation and by epitaxial growth.

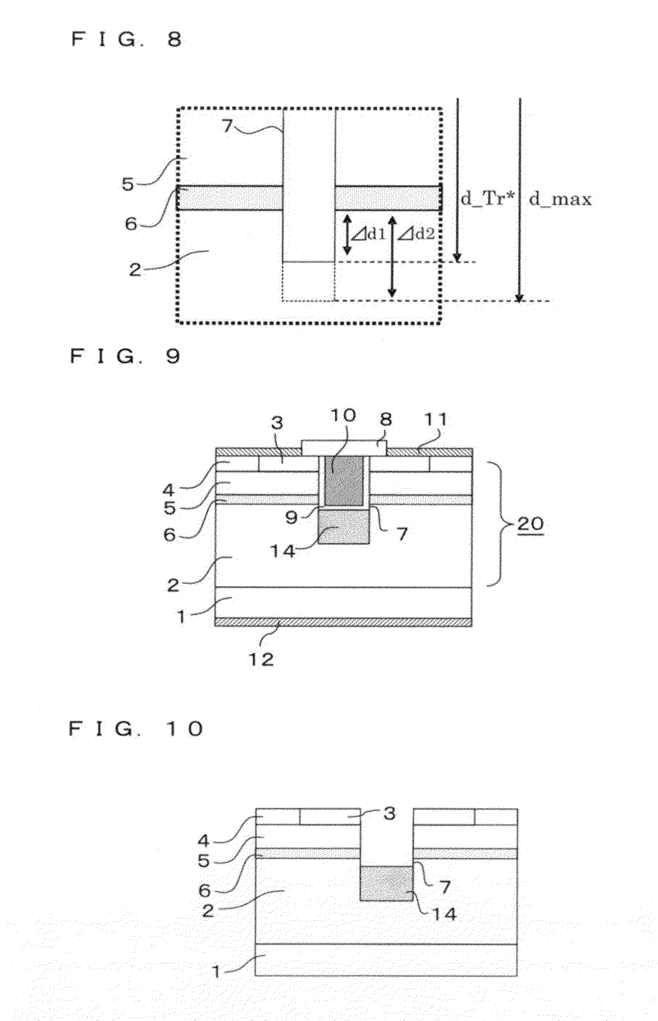

Next, the depth d_Tr of the trench 7 will be described. FIG. 8 is a sectional view, on an enlarged scale, of the trench 7 and its surroundings in the step of forming the trench 7 (FIG. 4). It is necessary to take variations during the formation of the trench 7 into consideration because the trench 7 is formed in the surface of the semiconductor layer 20 so as to extend through the depletion suppression layer 6 to reach the drift layer 2. When reactive ion etching is used to form the trench 7, the depth d_Tr of the trench 7 varies approximately ±15% with respect to a target depth d_Tr* although different depending on process conditions such as an etching gas. Then, the target depth d_Tr* which is set for the formation of the trench 7 is set so that a difference Δd1 between the target depth d_Tr* and the lower end of the depletion suppression layer 6 is equal to 15% of the target depth d_Tr*. This causes the trench 7 to extend through the depletion suppression layer 6 with reliability and prevents the trench 7 from being unnecessarily deep.

In such a case, the maximum value d_max of the depth of the trench 7 is obtained when 15% of the target depth d_Tr* is added to the target depth d_Tr and a difference Δd2 between the maximum depth d_max and the lower end of the depletion suppression layer 6 is equal to 30% of the target depth d_Tr*. When this is converted into the maximum depth d_max, the difference Δd2 between the maximum depth d_max and the lower end of the depletion suppression layer 6 is equal to 26% of the maximum depth d_max. In the silicon carbide semiconductor device 100 according to the first embodiment, the difference Δd2 between the lower end of the depletion suppression layer 6 and the depth d_Tr of the trench 7 (distance between the depletion suppression layer 6 and the bottom of the trench 7) is within 26% of the trench d_Tr.

With the aforementioned configuration, the silicon carbide semiconductor device 100 according to the first embodiment produces effects to be described below. In the first embodiment, the depletion suppression layer 6 provided between the body region 5 and the drift layer 2 suppresses the depletion layer extending from the body region 5 toward the drift layer 2. Thus, the depletion layer extending from the body region 5 is prevented from extending abruptly after reaching the inside of the drift layer 2 having a low n-type impurity concentration. As a result, this suppresses the prevention of lateral current diffusion in the drift layer 2 due to the depletion layer extending from the body region 5 to decrease the ON-state resistance.

The depletion suppression layer 6 is not intended to diffuse current by passing current through the depletion suppression layer 6 itself having an n-type impurity concentration higher than that of the drift layer 2, but is specialized to simply suppress the depletion layer extending from the body region 5 as mentioned above. Little current flows in the depletion suppression layer 6 except around the side surfaces of the trench 7. The depletion suppression layer 6 differs in object and function from the conventionally used current diffusion layer (CSL: Current Spread layer) in this way. The thickness of the depletion suppression layer 6 is set to 60 to 310 nm, that is, the minimum thickness required to suppress the depletion layer extending from the body region 5. This allows the depth of the trench 7 extending through the depletion suppression layer 6 to be made shallower by the amount corresponding to setting the thickness of the depletion suppression layer 6 to the minimum thickness.

The specific depth of the trench 7 may be shallower than at least the value obtained by adding the depletion layer width calculated using Equation (1) from the p-type impurity concentration of the body region 5, the n-type impurity concentration of the drift layer 2 and the ON-state voltage to the depth to the body region 5. This relieves the electric field in the bottom portion of the trench 7 to suppress the dielectric breakdown of the gate insulation film 9 and the like, thereby improving the breakdown voltage.

Also, the thickness of the depletion suppression layer 6 is within 100% to 130% of the depletion layer width ln at room temperature which is calculated using Equation (1) from the p-type impurity concentration of the body region 5 and the n-type impurity concentration of the depletion suppression layer 6. This allows the suppression of the depletion layer extending from the body region 5 even when a temperature change occurs. While the formation of the depletion suppression layer 6 by ion implantation is taken into consideration, the thickness of the depletion suppression layer 6 is set to 60 to 310 nm in consideration for the tail width of the impurity concentration during the ion implantation. Thus, there is no danger that the suppression of depletion is insufficient because of the decrease in impurity concentration in the tail part.

Further, the trench 7 is formed in the first embodiment so that the difference Δd2 between the lower end of the depletion suppression layer 6 and the depth d_Tr of the trench 7 is within 26% of the trench d_Tr in consideration for variations in the process for the formation of the trench 7. Thus, the corners of the trench 7 are included inside the depletion suppression layer 6. This suppresses the increase in electric field concentration at the corners of the trench 7 and achieves an improvement in breakdown voltage because of the minimum depth of the trench 7.

The silicon carbide semiconductor device 100 according to the first embodiment may be modified so that a protective layer 14 is provided in the bottom portion of the trench 7, as shown in FIG. 9. The protective diffusion layer 14 is a p-type semiconductor layer provided in the bottom portion of the trench 7. The protective diffusion layer 14 has a p-type impurity concentration of 5.0×10¹⁷ to 5.0×10¹⁸ cm⁻³. In such a case, the protective diffusion layer 14 relieves the electric field in the bottom portion of the trench 7 to achieve an improvement in breakdown voltage, but there is apprehension that the depletion layer extending from the protective diffusion layer 14 limits an ON-state current path to increase the ON-state resistance. However, the provision of the depletion suppression layer 6 in the first embodiment suppresses the depletion layer extending from the well region 5 to diffuse the ON-state current laterally. Thus, the increase in the ON-state resistance is suppressed by the lateral current diffusion even when the depletion layer extends from the protective diffusion layer 14.

The distance in the depth direction between the upper end of the protective diffusion layer 14 and the lower end of the depletion suppression layer 7 (the distance between the upper end of the protective diffusion layer 14 and the lower end of the depletion suppression layer 7) is not greater than 26% of the distance from the surface of the drift layer 2 to the upper end of the protective diffusion layer 14.

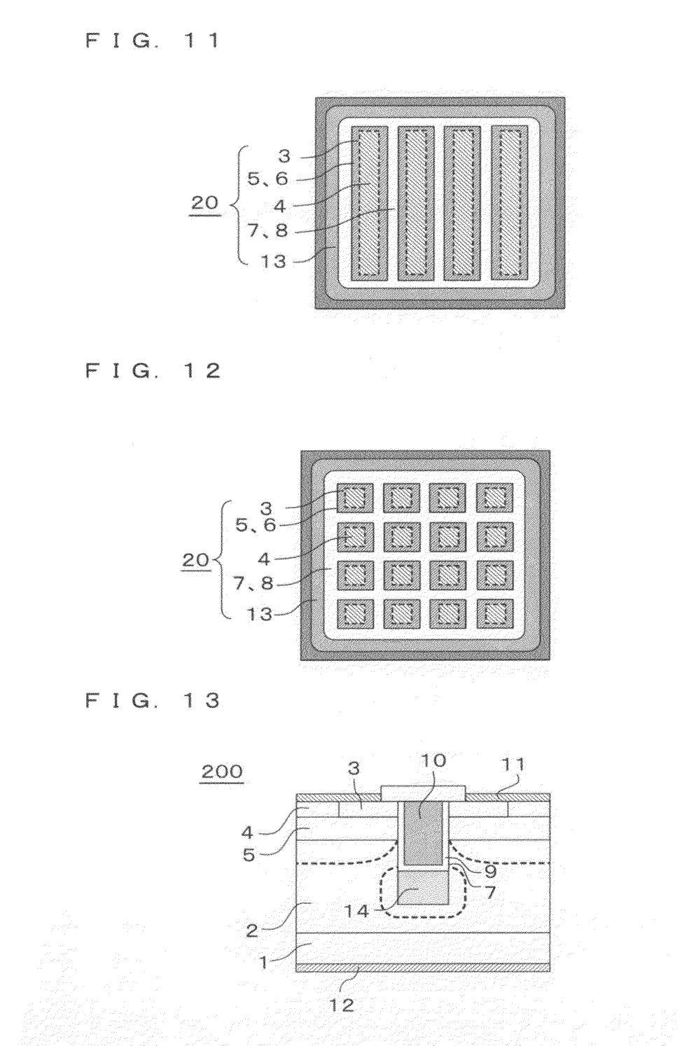

The protective diffusion layer 14 is formed in the drift layer 2 in the bottom portion of the trench 7 by implanting ions into the bottom portion of the trench 7, as shown in FIG. 10, after the formation of the trench 7 and before the formation of the gate insulation film 9. The formation of the protective diffusion layer 14 is not limited to the aforementioned configuration. The protective diffusion layer 14 may be formed by previously implanting ions into the drift layer 2 or by epitaxial growth in the bottom portion in the trench after the formation of the trench 7 deeper by the amount corresponding to the thickness of the protective diffusion layer 14.

The present invention is not limited by the arrangement of cells. As shown in FIGS. 11 and 12, the cells may be arranged in a striped pattern and in a lattice pattern, for example. When the cells are arranged in a lattice pattern, the cells need not be in alignment, and the cells may be polygonal in shape or include corners having a curvature. The source regions 3 and the body contact regions 4 are formed in a striped pattern or in an island pattern, and the body regions 5 and the depletion suppression layers 6 are formed in the same pattern under the source regions 3 and the body contact regions 4 in a stacked manner. The trench 7 is formed in a striped pattern or in a lattice pattern so as to contact the side surfaces of the source regions 3. In a termination region 13 around the outer periphery of the pattern, a p-type impurity layer is formed on the surface of the semiconductor layer 20 or p-type impurity layer is formed in the bottom surface obtained by etching a trench.

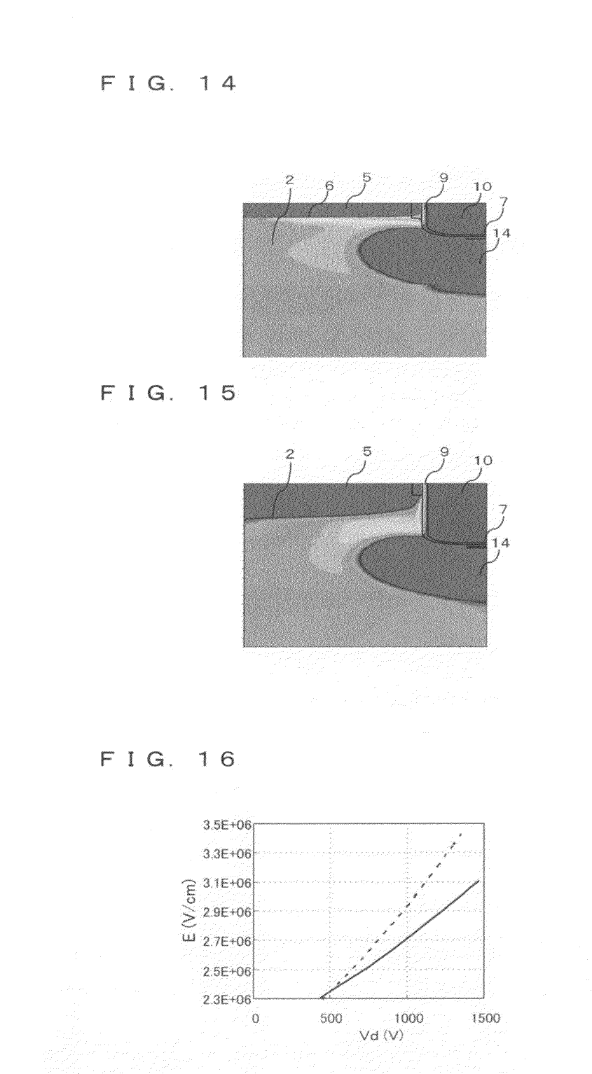

The effect of decreasing the ON-state resistance and the effect of improving the breakdown voltage in the first embodiment as described above will be described in conjunction with a comparative example. FIG. 13 is a sectional view showing a silicon carbide semiconductor device 200 according to a comparative example of the first embodiment. In FIG. 13, broken lines represent depletion layers extending from the well region 5 and the protective layer 14. As shown in FIG. 13, the silicon carbide semiconductor device 200 according to the comparative example is different from the first embodiment in not including the depletion suppression layer 6 and in the depth of the trench 7. A comparison will be made herein in a case where the protective layer 14 is provided in the bottom portion of the trench 7.

FIG. 14 shows a simulation result of an ON-state current distribution of the silicon carbide semiconductor device according to the first embodiment, and corresponds to FIG. 9. FIG. 15 shows a simulation result of an ON-state current distribution of the silicon carbide semiconductor device according to the comparative example of the first embodiment, and corresponds to FIG. 13. In FIGS. 14 and 15, regions are shown as more lightly shaded with the increase in current density. In the simulation, the drift layer 2 has an impurity concentration of 1.0×10¹⁶ cm⁻³; the well region 5 has an impurity concentration of 1.0×10¹⁸ cm⁻³; the depletion suppression layer 6 has an impurity concentration of 1.0×10¹⁷ cm⁻³; and the trench 7 of the silicon carbide semiconductor device according to the first embodiment is 0.4 μm shallower than that of the silicon carbide semiconductor device 200 according to the comparative example.

In the silicon carbide semiconductor device according to the first embodiment, as shown in FIG. 14, it is found that the provision of the depletion suppression layer 6 suppresses the depletion layer extending from the body region 5, so that the ON-state current expands laterally away from the trench 7. In the silicon carbide semiconductor device 200 according to the comparative example, as shown in FIG. 15, it is found that the depletion layer extending from the body region 5 expands to the drift layer 2, so that the lateral expansion of the ON-state current is suppressed by the depletion layer. As a result, it is confirmed that the simulation result shown in FIG. 14 can decrease the ON-state resistance [mΩcm²] by approximately 10%, as compared with that in FIG. 15.

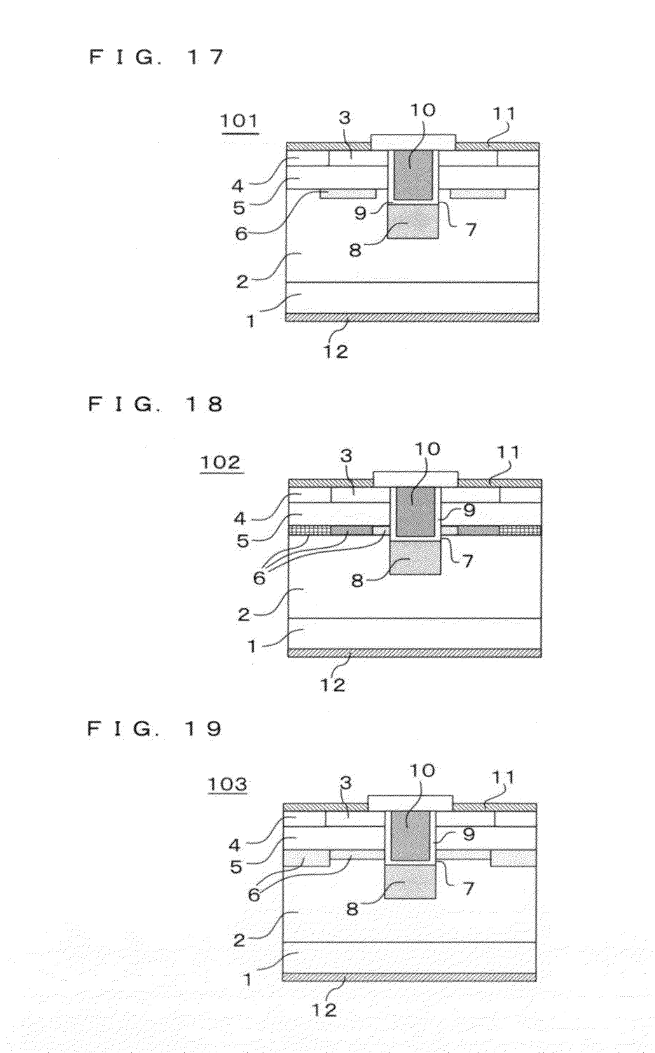

FIG. 16 shows a simulation result denoting a maximum electric field strength in the first embodiment and in the comparative example. In FIG. 16, the ordinate represents an electric field strength E [V/cm] in the silicon carbide semiconductor device, and the abscissa represents a drain voltage Vd [V]. In FIG. 16, a solid curve denotes the maximum electric field strength in the first embodiment, and a dotted curve denotes the maximum electric field strength in the comparative example.

When the protective layer 14 is provided in the bottom portion of the trench 7 as in the comparative example, the path of the ON-state current is also limited by the depletion layer extending from the protective layer 14, so that the increase in ON-state resistance is especially feared. It is hence necessary that the trench 7 of the silicon carbide semiconductor device 200 according to the comparative example is made deeper to ensure the ON-state current path. As a result, it is found that the silicon carbide semiconductor device according to the first embodiment is capable of decreasing the maximum electric field strength in the semiconductor layer 20, i.e. the electric field strength at the corners of the trench 7, as shown in FIG. 16 because the silicon carbide semiconductor device according to the first embodiment is 0.4 μm shallower than the silicon carbide semiconductor device 200 according to the comparative example. Thus, it is confirmed that the first embodiment can increase the breakdown voltage by approximately 10%, as compared with the comparative example.

As described above, the silicon carbide semiconductor device 100 according to the first embodiment, which includes the depletion suppression layer 6, suppresses the depletion layer extending from the body region 5 to achieve the decrease in ON-state resistance. Also, the trench 7 in the silicon carbide semiconductor device 100 according to the first embodiment is made shallower by setting the thickness of the depletion suppression layer 6 to the minimum required thickness. This achieves an improvement in breakdown voltage to improve a trade-off between the ON-state resistance and the breakdown voltage.

### Second Embodiment

In the first embodiment, the decrease in ON-state resistance and the improvement in breakdown voltage are achieved by adjusting the thickness of the depletion suppression layer 6 and the like. The present invention, however, is not limited to this. The position where the depletion suppression layer 6 is formed may be adjusted.

FIG. 17 is a sectional view showing a silicon carbide semiconductor device 101 according to a second embodiment. Like reference numerals and characters are used in FIG. 17 to designate components identical with or corresponding to those shown in FIG. 1. Because the second embodiment is different from the first embodiment in the position where the depletion suppression layer 6 is formed, other components will not be described.

In the second embodiment, the depletion suppression layer 6 is partially formed in non-contacting spaced-apart relationship with the trench 7, and extends to a portion immediately under the body contact region 4. As in the first embodiment, the depletion suppression layer 6 has an impurity concentration of not less than 1.0×10¹⁷, more preferably in the range of 2.0×10¹⁷ to 5.0×10¹⁷ cm⁻³. The thickness of the depletion suppression layer 6 is only required to be greater than the depletion layer width ln at room temperature calculated using Equation (1) from the p-type impurity concentration of the body region 5 and the n-type impurity concentration of the depletion suppression layer 6 so as to suppress the depletion layer with reliability. More specifically, it is preferable that the thickness of the depletion suppression layer 6 is at least 0.06 μm or more. The depletion suppression layer 6 may be formed in spaced-apart relationship with the trench 7 and in contact with the entire lower part of the body contact region 4, as shown in FIG. 17. However, the depletion suppression layer 6 may be formed in contact with the trench 7 and extend to a portion immediately under the body contact region 4. In such a case, the depletion suppression layer 6 is formed immediately under the body region 5, and more specifically immediately under the body contact region 4, in a spaced-apart manner.

A method for forming the depletion suppression layer 6 in the second embodiment is such that an implantation mask is used to form a region not implanted with n-type impurities during the formation of the depletion suppression layer 6 by ion implantation, whereby the depletion suppression layer 6 is partially formed. For the formation of the depletion suppression layer 6 by epitaxial growth, an n-type epitaxial layer may be partially formed in a portion where the depletion suppression layer 6 is to be formed. Alternatively, an n-type epitaxial layer may be formed entirely and etched away in a portion where the depletion suppression layer is not formed, and then an upper layer part may be epitaxially grown on that portion. This provides the silicon carbide semiconductor device 101 as shown in FIG. 17.

The silicon carbide semiconductor device 101 according to the second embodiment produces effects to be described below. First, when the depletion suppression layer 6 is formed in spaced-apart relationship with the trench 7, the depletion suppression layer 6 having a high impurity concentration does not contact the trench 7. That is, the corners of the trench 7 are not included inside the depletion suppression layer 6. This provides the shallow trench 7 to improve the breakdown voltage. In the portion spaced apart the trench 7, the depletion suppression layer 6 is formed to suppress the depletion layer extending from the body region 5. This achieves the lateral diffusion of the ON-state current to decrease the ON-state resistance.

When the body region 5 is forming by ion implantation, there are cases where a channel length is shortened because of an overlap between the impurity concentration profiles of the region (channel region) where a channel in the body region 5 is formed and the depletion suppression layer 6. However, the second embodiment is capable of maintaining a long channel length because the depletion suppression layer 6 is not formed immediately under the channel region.

Further, the depletion suppression layer 6 is formed in spaced-apart relationship with the trench 7 and extends to the portion immediately under the body contact region 4. In other words, a region where the depletion suppression layer 6 is not formed is present immediately under the body contact region 4. In this region, the depletion layer may be extended from the body region 5 in the OFF state to relieve the electric field in the drift layer 2.

### Third Embodiment

In the first embodiment, the decrease in ON-state resistance and the improvement in breakdown voltage are achieved by adjusting the thickness of the depletion suppression layer 6 and the like. The present invention, however, is not limited to this. The impurity concentration may be adjusted in the depletion suppression layer 6.

FIG. 18 is a sectional view showing a silicon carbide semiconductor device 102 according to a third embodiment. Like reference numerals and characters are used in FIG. 18 to designate components identical with or corresponding to those shown in FIG. 1. Because the third embodiment is different from the first embodiment in the impurity concentration in the depletion suppression layer 6, other components will not be described.

In the third embodiment of the present invention, the depletion suppression layer 6 has a gradation in impurity concentration in a planar direction, as shown in FIG. 18. More specifically, the depletion suppression layer 6 has a gradation in impurity concentration getting higher with increasing distance from the trench side surfaces.

The concentration gradation may have a plurality of concentration steps to change step by step or may change gradually without steps. For step-by-step changes in impurity concentration, an n-type layer having partially different concentrations is formed by performing ion implantation a plurality of times using a plurality of masks. For gradual change, rather than step-by-step changes, in impurity concentration, a desired structure is formed by implanting n-type impurity ions using a gray tone mask. At this time, the impurity concentration of the depletion suppression layer 6 may be formed in accordance with the impurity concentration distributions of the p-type body region 5 lying over and adjacent to the depletion suppression layer 6 and the body contact region 4 so that the n-type impurity concentration is lower in a portion having a lower p-type impurity concentration such as near a channel and the n-type impurity concentration is higher in a portion having a higher p-type impurity concentration such as a portion under the body contact region 4.

The silicon carbide semiconductor device 102 according to the third embodiment produces effects to be described below. The extension of the depletion layer from the body region 5 increases with increasing distance from the trench 7 because of the influence of the potential of the gate electrode 10. Thus, in the third embodiment, the n-type impurity concentration of the depletion suppression layer 6 is higher in the region farther from the trench 7 where the extension of the depletion layer is large to suppress the depletion layer extending from the body region 5 with reliability. The impurity concentration of the depletion suppression layer 6 around the trench 7 is lower than that in the region far from the trench 7. However, the depletion layer is suppressed also around the trench 7 because the extension of the depletion layer from the body region 5 is also small. Further, the electric field strength applied to the side walls and the bottom surface of the trench 7 is held low because of the low impurity concentration around the trench 7. Also, the low impurity concentration immediately under the channel region causes a small overlap between the impurity concentration profiles of the channel region and the depletion suppression layer 6 to maintain a long channel length.

### Fourth Embodiment

In the first embodiment, the decrease in ON-state resistance and the improvement in breakdown voltage are achieved by adjusting the thickness of the depletion suppression layer 6 and the like. The present invention, however, is not limited to this. The in-plane thickness of the depletion suppression layer 6 may be adjusted.

FIG. 19 is a sectional view showing a silicon carbide semiconductor device 103 according to a fourth embodiment. Like reference numerals and characters are used in FIG. 19 to designate components identical with or corresponding to those shown in FIG. 1. Because the fourth embodiment is different from the first embodiment in the in-plane thickness of the depletion suppression layer 6, other components will not be described.

In the fourth embodiment, as shown in FIG. 19, the depletion suppression layer 6 is thicker to have an excess thickness in a region far from the trench 7. Specifically, the in-plane thickness of the depletion suppression layer 6 has two different levels. That is, the thickness of part of the depletion suppression layer 6 which is in contact with the trench 7 is equal to that of the first embodiment, and the thickness of part of the depletion suppression layer 6 which is far from the trench 7 is greater. The thickness of the depletion suppression layer 6 may have a plurality of levels to change step by step or may change gradually without steps. For step-by-step changes in thickness, an n-type layer having partially different thicknesses is formed by performing ion implantation a plurality of times using a plurality of masks. For gradual change, rather than step-by-step changes, in thickness, n-type impurity ions are implanted using an inclined resist mask and the like, whereby the depletion suppression layer 6 having a depth in accordance with the shape of the mask is formed.

Around the trench 7, the provision of the depletion suppression layer 6 according to the fourth embodiment suppresses the depletion layer extending from the body region 5 to achieve the decrease in ON-state resistance, as in the first embodiment. Also, the trench 7 is made shallower by setting the thickness of the depletion suppression layer 6 to the minimum required thickness. This achieves an improvement in breakdown voltage to improve a trade-off between the ON-state resistance and the breakdown voltage.

In the region far from the trench 7 such as the region immediately under the body contact region 4, the increased thickness of the depletion suppression layer 6 increases the lateral diffusion of the ON-state current to further decrease the ON-state resistance, as in the conventional current diffusion layer.

The embodiments according to the present invention may be arbitrarily combined, modified and omitted, as appropriate, within the scope of the present invention.

### REFERENCE SIGNS LIST

1 Substrate; 2 Drift layer; 3 Source region; 4 Body contact region; 5 Body region; 6 Depletion suppression layer; 7 Trench; 8 Interlayer dielectric film; 9 Gate insulation film; 10 Gate electrode; 11 Source electrode; 12 Drain electrode; 13 Termination region; 14 Protective diffusion layer; 20 Semiconductor layer; and 100, 101, 102, 103, 200 Silicon carbide semiconductor devices.

1. A silicon carbide semiconductor device comprising:
a drift layer of a first conductivity type made of a silicon carbide semiconductor;
a depletion suppression layer of the first conductivity type formed on said drift layer and having a first conductivity type impurity concentration higher than that of said drift layer;
a body region of a second conductivity type formed on said depletion suppression layer;
a trench extending through said body region and said depletion suppression layer to reach said drift layer; and
a gate insulation film formed along bottom and side surfaces of said trench,
wherein said depletion suppression layer has a thickness equal to or greater than 0.06 μm and equal to or less than 0.31 μm, and
the first conductivity type impurity concentration of said depletion suppression layer is equal to or greater than 1.0×10¹⁷ cm⁻³.

2-14. (canceled)

15. The silicon carbide semiconductor device according to claim 1, wherein
the second conductivity type impurity concentration of said body region is 1.0×10¹⁴ to 1.0×10¹⁸ cm⁻³.

16. The silicon carbide semiconductor device according to claim 1, wherein
a distance between said depletion suppression layer and a bottom portion of said trench is not greater than 26% of the depth of said trench as measured from a surface of said drift layer.

17. The silicon carbide semiconductor device according to claim 1, wherein
the first conductivity type impurity concentration of said depletion suppression layer is 2.0×10¹⁷ to 5.0×10¹⁷ cm⁻³.

18. The silicon carbide semiconductor device according to claim 1, wherein
said depletion suppression layer is formed on said drift layer and spaced apart from said trench.

19. The silicon carbide semiconductor device according to claim 1, wherein
said depletion suppression layer is formed under said body region in a spaced-apart manner and to be adjacent through said drift layer.

20. The silicon carbide semiconductor device according to claim 1, wherein
said depletion suppression layer on said drift layer extends in contact with said trench, and the thickness of said depletion suppression layer increases with increasing distance from said trench.

21. The silicon carbide semiconductor device according to claim 1, wherein
said depletion suppression layer on said drift layer extends in contact with said trench, and the first conductivity type impurity concentration of said depletion suppression layer increases with increasing distance from said trench.

22. The silicon carbide semiconductor device according to claim 1, further comprising
a protective diffusion layer of the second conductivity type formed in said drift layer under said trench.

23. The silicon carbide semiconductor device according to claim 22, wherein
a distance between the upper end of said protective diffusion layer and the lower end of said depletion suppression layer is not greater than 26% of a distance between a surface of said drift layer and the upper end of said protective diffusion layer.

24. A silicon carbide semiconductor device comprising:
a drift layer of a first conductivity type made of a silicon carbide semiconductor;
a depletion suppression layer of the first conductivity type formed on said drift layer and having a first conductivity type impurity concentration higher than that of said drift layer;
a body region of a second conductivity type formed on said depletion suppression layer;
a trench extending through said body region and said depletion suppression layer to reach said drift layer; and
a gate insulation film formed along bottom and side surfaces of said trench,
wherein the first conductivity type impurity concentration of said depletion suppression layer is equal to or greater than 1.0×10¹⁷ cm⁻³, and
the thickness of said depletion suppression layer is equal to or greater than 100% and equal to or less than 130% of the thickness of a depletion layer closer to said depletion suppression layer, the thickness of the depletion layer being calculated from the second conductivity type impurity concentration of said body region and the first conductivity type impurity concentration of said depletion suppression layer.

25. The silicon carbide semiconductor device according to claim 24, wherein
the second conductivity type impurity concentration of said body region is 1.0×10¹⁴ to 1.0×10¹⁸ cm⁻³.

26. The silicon carbide semiconductor device according to claim 24, wherein
a distance between said depletion suppression layer and a bottom portion of said trench is not greater than 26% of the depth of said trench as measured from a surface of said drift layer.

27. The silicon carbide semiconductor device according to claim 24, wherein
the first conductivity type impurity concentration of said depletion suppression layer is 2.0×10¹⁷ to 5.0×10¹⁷ cm⁻³.

28. The silicon carbide semiconductor device according to claim 24, wherein
said depletion suppression layer is formed on said drift layer and spaced apart from said trench.

29. The silicon carbide semiconductor device according to claim 24, wherein
said depletion suppression layer is formed under said body region in a spaced-apart manner and to be adjacent through drift layer.

30. The silicon carbide semiconductor device according to claim 24, wherein
said depletion suppression layer on said drift layer extends in contact with said trench, and the thickness of said depletion suppression layer increases with increasing distance from said trench.

31. The silicon carbide semiconductor device according to claim 24, wherein
said depletion suppression layer on said drift layer extends in contact with said trench, and the first conductivity type impurity concentration of said depletion suppression layer increases with increasing distance from said trench.

32. The silicon carbide semiconductor device according to claim 24, further comprising
a protective diffusion layer of the second conductivity type formed in said drift layer under said trench.

33. The silicon carbide semiconductor device according to claim 32, wherein
a distance between the upper end of said protective diffusion layer and the lower end of said depletion suppression layer is not greater than 26% of a distance between a surface of said drift layer and the upper end of said protective diffusion layer.
